(19) United States
(12) Patent Application Publication
(10) Pub. No.: US 2024/0379281 A1
(43) Pub. Date: Nov. 14, 2024

(54) CIRCUIT COMPONENT, ELECTRONIC DEVICE AND METHOD FOR PRODUCING CIRCUIT COMPONENT

(71) Applicant: ROHM CO., LTD., Kyoto-shi (JP)

(72) Inventors: Tatsuya MIYAZAKI, Kyoto-shi (JP); Kazunori FUJI, Kyoto-shi (JP); Yuta OKAWAUCHI, Kyoto-shi (JP)

(21) Appl. No.: 18/782,708

(22) Filed: Jul. 24, 2024

Related U.S. Application Data
(63) Continuation of application No. PCT/JP2023/000779, filed on Jan. 13, 2023.

(30) Foreign Application Priority Data
Feb. 3, 2022 (JP) 2022-015681

(51) Int. Cl. H01F 27/28; H01F 27/24; H01F 27/32; H01F 41/02; H01F 41/04; H01F 41/12; H05K 1/18

(52) U.S. Cl. CPC H01F 27/2804; H01F 27/24; H01F 27/324; H01F 41/0206; H01F 41/041; H01F 41/12; H05K 1/181; H01F 2027/2809

(57) ABSTRACT

A circuit component includes a magnetic layer, a first insulating layer, a second insulating layer, and a wiring. The first insulating layer is stacked on a first side in a thickness direction relative to the magnetic layer, and the second insulating layer is stacked on a second side in the thickness direction relative to the magnetic layer. The wiring includes a first wiring layer located between the magnetic layer and the first insulating layer, a second wiring layer located on the second side in the thickness direction relative to the second insulating layer, and a first through-wiring segment penetrating the magnetic layer and the second insulating layer and connected to the first wiring layer and the second wiring layer. The first wiring layer, the second wiring layer, and the first through-wiring segment constitute a winding segment.

### TECHNICAL FIELD

The present disclosure relates to a circuit component and an electronic device. The present disclosure also relates to a method for manufacturing a circuit component.

### BACKGROUND ART

Circuit components configured as inductors are used as components of various electronic devices. JP-B-6401119 discloses an example of a conventional circuit component. The circuit component disclosed in JP-B-6401119 includes a magnetic core and a conductor coil that are disposed on a module substrate. The magnetic core is an annular component made of a magnetic material and enclosed within the resin layer that forms the module substrate. The conductor coil is wound around the magnetic core within the module substrate.

### BRIEF DESCRIPTION OF THE DRAWINGS

FIG. 1 is a perspective view of a circuit component according to a first embodiment of the present disclosure.

FIG. 2 is a plan view showing an important portion of the circuit component according to the first embodiment of the present disclosure.

FIG. 3 is a plan view showing an important portion of the circuit component according to the first embodiment of the present disclosure.

FIG. 4 is a bottom view of the circuit component according to the first embodiment of the present disclosure.

FIG. 5 is a sectional view taken along line V-V in FIG. 2.

FIG. 6 is a sectional view taken along line VI-VI in FIG. 2.

FIG. 7 is an enlarged sectional view showing an important portion of the circuit component according to the first embodiment of the present disclosure.

FIG. 8 is an enlarged sectional view showing an important portion of the circuit component according to the first embodiment of the present disclosure.

FIG. 9 is an enlarged sectional view showing an important portion of the circuit component according to the first embodiment of the present disclosure.

FIG. 10 is a sectional view illustrating a method for manufacturing a circuit component according to the first embodiment of the present disclosure.

FIG. 11 is a sectional view illustrating the method for manufacturing a circuit component according to the first embodiment of the present disclosure.

FIG. 12 is a sectional view illustrating the method for manufacturing a circuit component according to the first embodiment of the present disclosure.

FIG. 13 is a sectional view illustrating the method for manufacturing a circuit component according to the first embodiment of the present disclosure.

FIG. 14 is a sectional view illustrating the method for manufacturing a circuit component according to the first embodiment of the present disclosure.

FIG. 15 is a sectional view illustrating the method for manufacturing a circuit component according to the first embodiment of the present disclosure.

FIG. 16 is a sectional view illustrating the method for manufacturing a circuit component according to the first embodiment of the present disclosure.

FIG. 17 is a sectional view illustrating the method for manufacturing a circuit component according to the first embodiment of the present disclosure.

FIG. 18 is a sectional view illustrating the method for manufacturing a circuit component according to the first embodiment of the present disclosure.

FIG. 19 is a sectional view illustrating the method for manufacturing a circuit component according to the first embodiment of the present disclosure.

FIG. 20 is a sectional view illustrating the method for manufacturing a circuit component according to the first embodiment of the present disclosure.

FIG. 21 is a sectional view illustrating the method for manufacturing a circuit component according to the first embodiment of the present disclosure.

FIG. 22 is a sectional view illustrating the method for manufacturing a circuit component according to the first embodiment of the present disclosure.

FIG. 23 is a sectional view illustrating the method for manufacturing a circuit component according to the first embodiment of the present disclosure.

FIG. 24 is a sectional view illustrating the method for manufacturing a circuit component according to the first embodiment of the present disclosure.

FIG. 25 is a sectional view illustrating the method for manufacturing a circuit component according to the first embodiment of the present disclosure.

FIG. 26 is an enlarged sectional view showing an important portion of a first variation of the circuit component according to the first embodiment of the present disclosure.

FIG. 27 is a front view of an electronic device according to the first embodiment of the present disclosure.

FIG. 28 is a sectional view of a first variation of the electronic device according to the first embodiment of the present disclosure.

FIG. 29 is a sectional view of a second variation of the electronic device according to the first embodiment of the present disclosure.

FIG. 30 is a sectional view of a third variation of the electronic device according to the first embodiment of the present disclosure.

FIG. 31 is a plan view showing an important portion of the first variation of the circuit component according to the first embodiment of the present disclosure.

FIG. 32 is a plan view showing an important portion the first variation of the circuit component according to the first embodiment of the present disclosure.

FIG. 33 is a sectional view of a circuit component according to a second embodiment of the present disclosure.

FIG. 34 is a plan view showing an important portion of a first variation of the circuit component according to the second embodiment of the present disclosure.

FIG. 35 is a plan view showing an important portion of the first variation of the circuit component according to the second embodiment of the present disclosure.

FIG. 36 is an enlarged sectional view of a variation of a magnetic layer of the circuit component according to the present disclosure.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels and are not intended to impose a specific order or sequence on the items modified by the terms.

In the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, “A surface A faces in a direction B (or faces a first side or a second side of the direction B) is not limited, unless otherwise specifically noted, to the situation where the surface A forms an angle of 90° with the direction B but includes the situation where the surface A is inclined with respect to the direction B.

### First Embodiment, Circuit Component A1

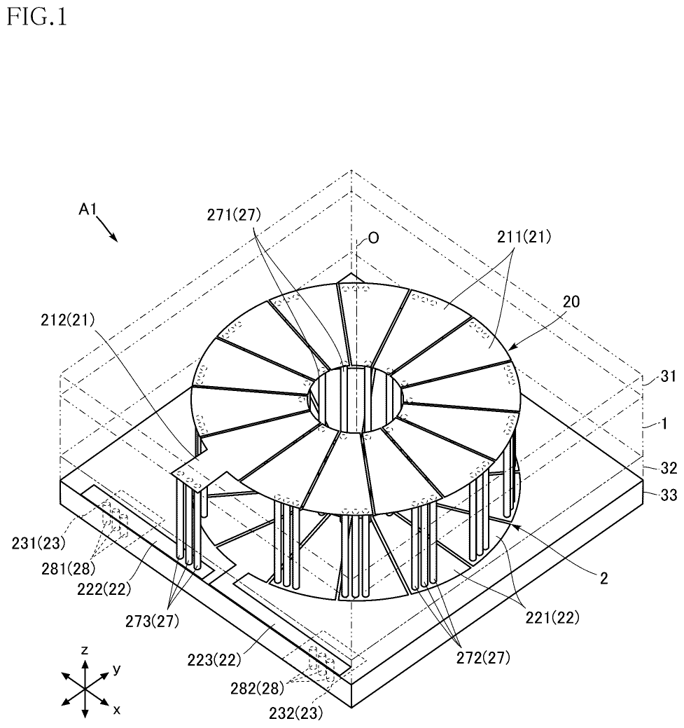

FIGS. 1 to 9 show a circuit component according to a first embodiment of the present disclosure. The circuit component A1 of the present disclosure includes a magnetic layer 1, a wiring 2, a first insulating layer 31, a second insulating layer 32, and a third insulating layer 33.

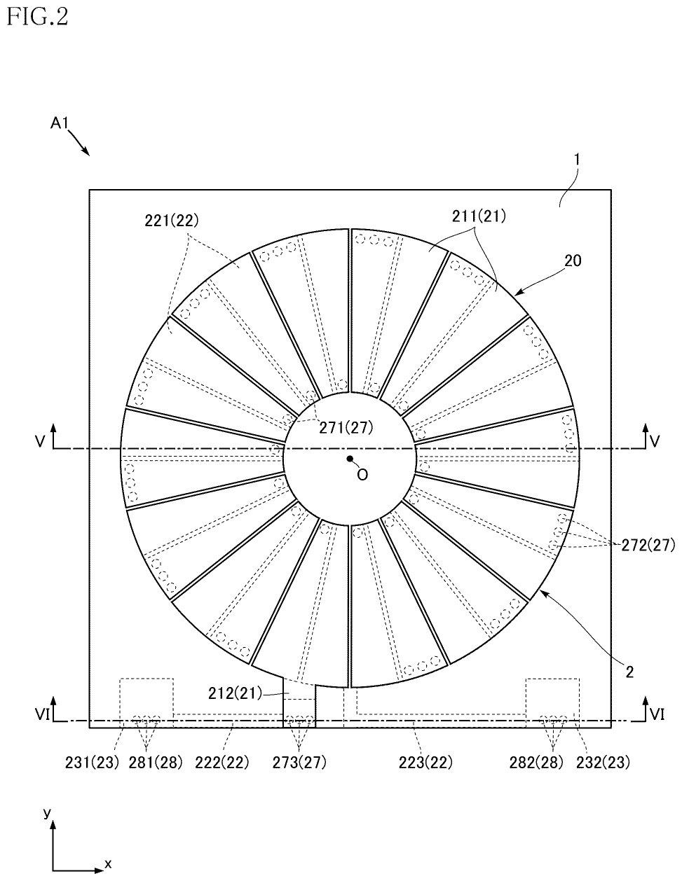

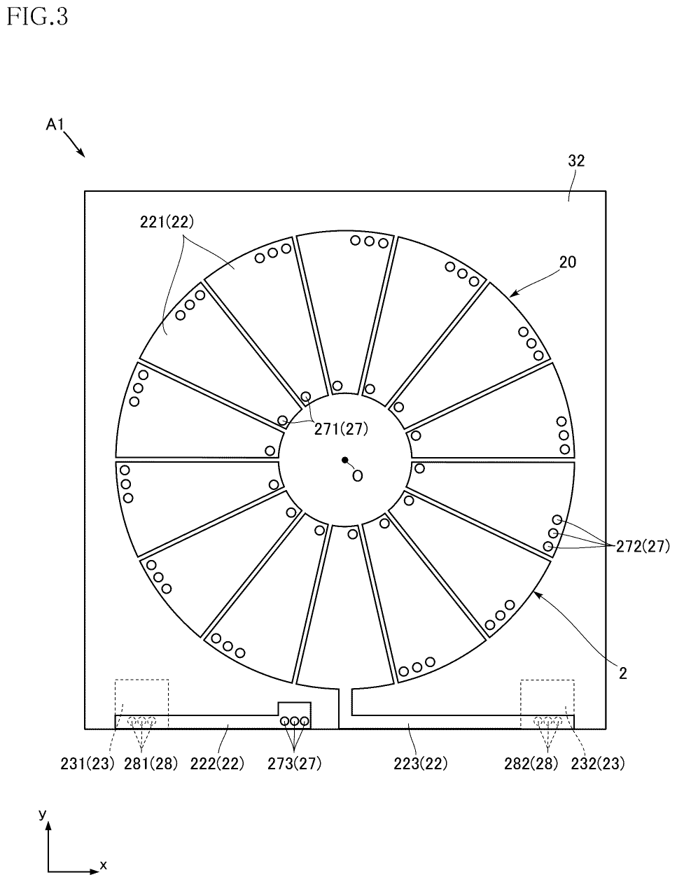

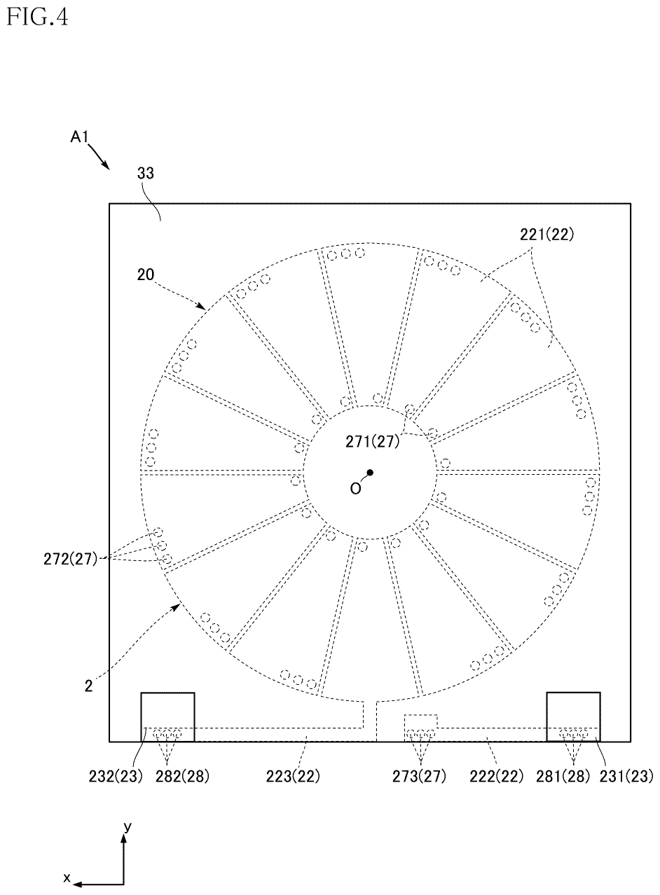

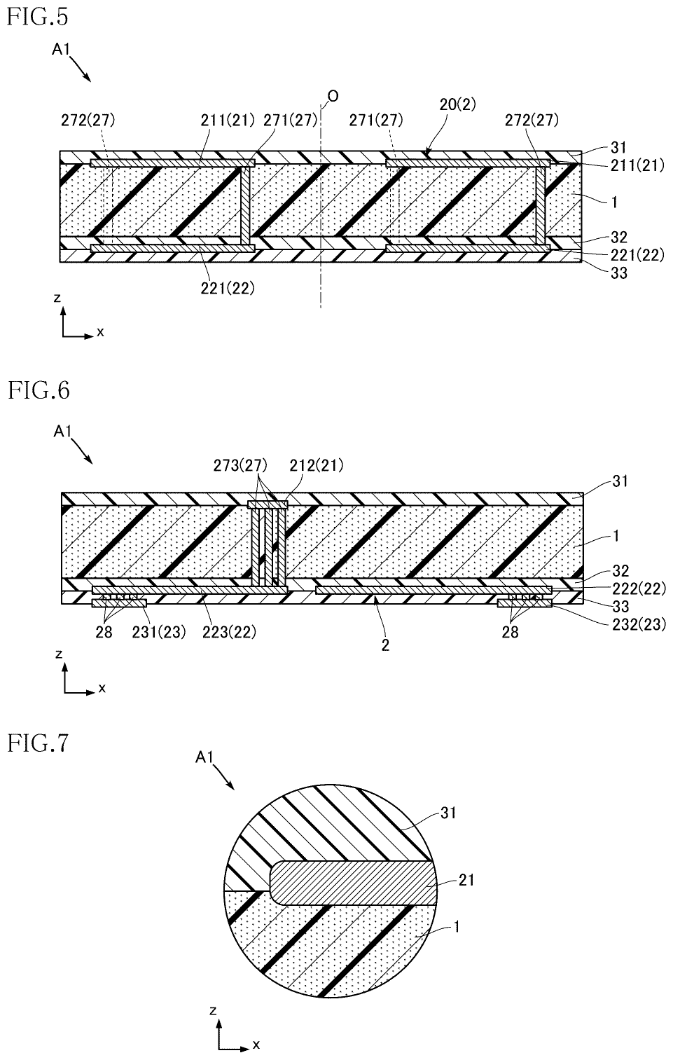

FIG. 1 is a perspective view of the circuit component A1. FIGS. 2 and 3 are plan views each showing an important portion of the circuit component A1. FIG. 4 is a bottom view of the circuit component A1. FIG. 5 is a sectional view taken along line V-V of FIG. 2. FIG. 6 is a sectional view taken along line VI-VI of FIG. 2. FIGS. 7 to 9 are enlarged sectional views showing the circuit component A1. In these figures, the z direction corresponds to the thickness direction of the present disclosure. FIG. 2 omits the first insulating layer 31, and the FIG. 3 omits the first wiring layer 21, the first insulating layer 31, and the magnetic layer 1.

The circuit component A1 is a magnetic component that exhibits inductance when an electric current flows through a winding segment 20 of the wiring 2. While the dimensions of the circuit component A1 are not limited, each of the x-direction dimension and the y-direction dimension may be about 1 to 10 mm, for example.

### Magnetic Layer 1:

The magnetic layer 1 has a thickness in the z direction and extends in the x and y directions. The magnetic layer 1 is made of a magnetic material and includes a segment that forms a magnetic core of the circuit component A1. The configuration of the magnetic layer 1 is not specifically limited, as long as its relative permeability and insulating property are suitable for a magnetic core. The magnetic layer 1 may be a layer made of a resin material containing magnetic bodies, or a substrate made of a magnetic material, such as ferrite. When a manufacturing method described below is used, the magnetic layer 1 is configured to allow for the formation of through-holes using laser light.

The thickness of the magnetic layer 1 in the z direction may be, but not limited to, 100 μm to 1 mm, for example.

### First Insulating Layer 31, Second Insulating Layer 32, Third Insulating Layer 33:

The first insulating layer 31, the second insulating layer 32, and the third insulating layer 33 are stacked with the magnetic layer 1. The first insulating layer 31, the second insulating layer 32, and the third insulating layer 33 made an insulating material. The specific are of configurations of the first insulating layer 31, the second insulating layer 32, and the third insulating layer 33 are not limited. In the present embodiment, the first insulating layer 31, the second insulating layer 32, and the third insulating layer 33 are made of a material that enables laser direct structuring (LDS), which is used in the production of molded interconnect devices (MIDs). Examples of such materials include a resin material containing a metal catalyst.

The first insulating layer 31 is stacked on a first side in the z direction relative to the magnetic layer 1. The second insulating layer 32 is stacked on a second side in the z direction relative to the magnetic layer 1. The third insulating layer 33 is stacked on the second side in the z direction relative to the second insulating layer 32. Note that the circuit component according to the present disclosure may omit the third insulating layer 33.

The thicknesses of the first insulating layer 31, the second insulating layer 32, and the third insulating layer 33 in the z direction are not limited. For example, the thickness of the first insulating layer 31 may be 10 μm to 1 mm, the thickness of the second insulating layer 32 may be 10 to 100 μm, and the thickness of the third insulating layer 33 may be 10 μm to 1 mm.

There is no limitation as to the technique used to form the stack of the magnetic layer 1, the first insulating layer 31, the second insulating layer 32, and the third insulating layer 33. For example, an adhesive layer (not shown) may be provided between adjacent layers. In another example, a paste of material for forming an appropriate layer is applied onto another layer and allowed to harden, resulting in the stack of the two layers.

### Wiring 2:

The wiring 2 provides the conductive paths for the circuit component A1 to function. The wiring 2 of the present embodiment includes a first wiring layer 21, a second wiring layer 22, a third wiring layer 23, a first through-wiring segment 27, and a second through-wiring segment 28. The material of the wiring 2 is not limited, and preferable examples include copper (Cu) and a copper (Cu) alloy.

As shown in FIGS. 5 and 6, the first wiring layer 21 is located between the first insulating layer 31 and the magnetic layer 1 in the z direction. As shown in FIGS. 1, 2, 5, and 6, the first wiring layer 21 of the present embodiment includes a plurality of first wiring segments 211 and a connecting wiring segment 212.

The first wiring segments 211 are arranged to surround a center O. In the illustrated example, the first wiring segments 211 are arranged in a circle around the center O with equal spacing. Each first wiring segment 211 has a tapered shape.

The connecting wiring segment 212 is connected to one of the first wiring segments 211 and extends in the y direction. The thickness of the first wiring layer 21 is not limited and may be 10 to 100 μm, for example. As shown in FIG. 7, in the present embodiment, the first wiring layer 21 is embedded in the first insulating layer 31 in the z direction. The first wiring layer 21 is also embedded in the magnetic layer 1 in the z direction. In one variation as shown in FIG. 26, the first wiring layer 21 may be embedded in the first insulating layer 31 but not in the magnetic layer 1. That is, the first wiring layer 21 may be thinner than the depth of the recesses in the first insulating layer 31. This also applies to the second wiring layer 22 and the third wiring layer 23 described below.

As shown in FIGS. 5 and 6, the second wiring layer 22 is located on the second side in the z direction relative to the magnetic layer 1 and between the second insulating layer 32 and the third insulating layer 33. As shown in FIGS. 1, 3, 5, and 6, the second wiring layer 22 of the present embodiment includes a plurality of second wiring segments 221, a connecting wiring segment 222, and a connecting wiring segment 223.

The second wiring segments 221 are arranged to surround the center O. In the illustrated example, the second wiring segments 221 are arranged in a circle around the center O with equal spacing. Each second wiring segment 221 has a tapered shape. As shown in FIG. 1, the first wiring segments 211 and the second wiring segments 221 are offset from each other by half the spacing between adjacent segments in the circumferential direction (the toroidal direction) around the center O as viewed in the z direction. That is, as viewed in the z direction, two first wiring segments 211 located next to each other partially overlap with one second wiring segment 221. Also, as viewed in the z direction, two second wiring segments 221 located next to each other partially overlap with one first wiring segment 211.

The connecting wiring segment 222 is spaced apart from the second wiring segments 221 in the y direction. The connecting wiring segment 222 has a shape extending in the x direction.

The connecting wiring segment 223 is connected to one of the second wiring segments 221. The connecting wiring segment 223 includes a first portion extending in the y direction from the one second wiring segment 221 and a second portion extending in the x direction from the first portion.

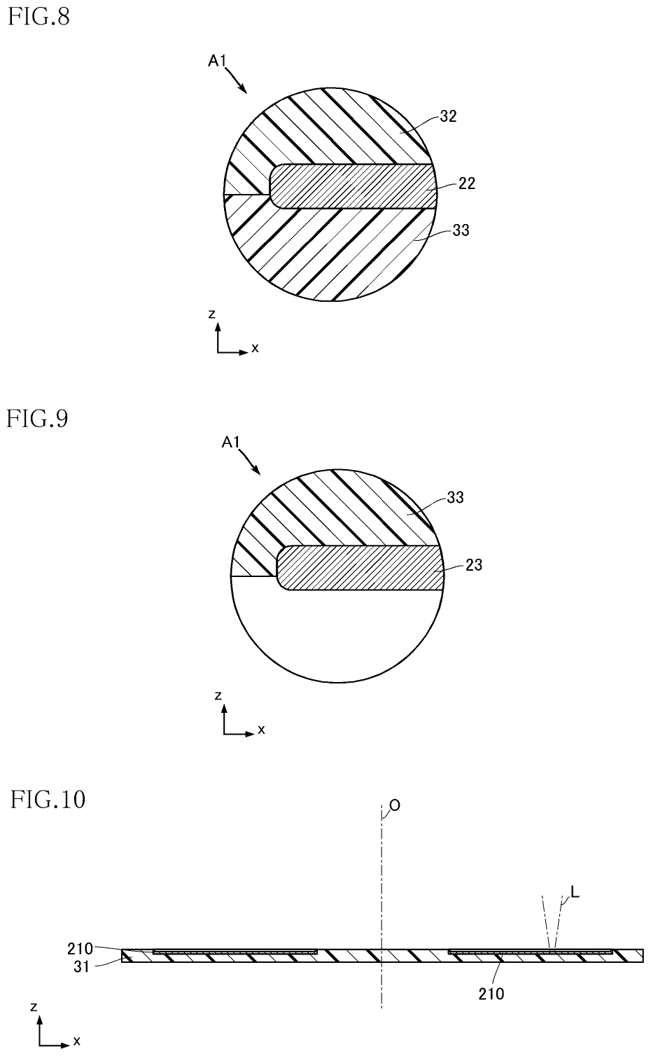

The thickness of the second wiring layer 22 is not limited and may be 10 to 100 μm, for example. As shown in FIG. 8, in the present embodiment, the second wiring layer 22 is embedded in the second insulating layer 32 in the z direction. The second wiring layer 22 is also embedded in the third insulating layer 33 in the z direction.

As shown in FIGS. 5 and 6, the third wiring layer 23 is disposed on the second side in the z direction relative to the third insulating layer 33. In the example shown in FIGS. 1 to 4 and 6, the third wiring layer 23 includes a terminal segment 231 and a terminal segment 232.

The terminal segment 231 is located closer to one end in the x direction. The terminal segment 232 is spaced apart from the terminal segment 231 in the x direction. The terminal segments 231 and 232 are used for mounting the circuit component A1. The terminal segments 231 and 232 may be provided with plating layers (not shown) covering their surfaces to improve solder wettability, or they may be provided with solder balls (not shown) on their surfaces.

The thickness of the third wiring layer 23 is not limited and may be 10 to 100 μm, for example. As shown in FIG. 9, in the present embodiment, the third wiring layer 23 is embedded in the third insulating layer 33 in the z direction.

The first through-wiring segment 27 penetrates the magnetic layer 1 and the second insulating layer 32 in the z direction as shown in FIGS. 5 and 6. The first through-wiring segment 27 is connected to the first wiring layer 21 and the second wiring layer 22. As shown in FIGS. 1 to 6, the first through-wiring segment 27 of the present embodiment includes a plurality of inner through-wiring segments 271, a plurality of outer through-wiring segments 272, and a plurality of connecting through-wiring segments 273.

As shown in FIGS. 1 to 5, each inner through-wiring segment 271 is connected to a first wiring segment 211 and a second wiring segment 221 that overlap with the inner through-wiring segment 271 as viewed in the z direction. The inner through-wiring segments 271 are located closer to the center O within the first wiring segments 211 and the second wiring segments 221. Each first wiring segment 211 is connected to only one of the two second wiring segments 221 that overlap with the first wiring segment 211 as viewed in the z direction, via an inner through-wiring segment 271. Also, each second wiring segment 221 is connected to only one of the two first wiring segments 211 that overlap with the second wiring segment 221 as viewed in the z direction, via an inner through-wiring segment 271. The number of inner through-wiring segments 271 is not limited.

As shown in FIGS. 1 to 5, each outer through-wiring segment 272 is connected to a first wiring segment 211 and a second wiring segment 221 that overlap with the outer through-wiring segment 272 as viewed in the z direction. The outer through-wiring segments 272 are located farther from the center O within the first wiring segments 211 and the second wiring segments 221. Each first wiring segment 211 is connected to only one of the two second wiring segments 221 that overlap with the first wiring segment 211 as viewed in the z direction, via an outer through-wiring segment 272. Also, each second wiring segment 221 is connected to only one of the two first wiring segments 211 that overlap with the second wiring segment 221 as viewed in the z direction, via an outer through-wiring segment 272. The number of the outer through-wiring segments 272 is not limited. In the present embodiment, the outer through-wiring segments 272 outnumber the inner through-wiring segments 271.

As shown in FIGS. 1 to 3, and 6, the connecting through-wiring segments 273 are connected to the connecting wiring segment 212 of the first wiring layer 21 and to the connecting wiring segment 222 of the second wiring layer 22.

As shown in FIGS. 1 to 4, and 6, the second through-wiring segments 28 penetrate the third insulating layer 33 in the z direction. The second through-wiring segments 28 are connected to the second wiring layer 22 and the third wiring layer 23. The second through-wiring segments 28 include those connected to the connecting wiring segment 223 of the second wiring layer 22 and to the terminal segment 231 of the third wiring layer 23. The second through-wiring segments 28 additionally include those connected to the connecting wiring segment 222 of the second wiring layer 22 and to the terminal segment 232 of the third wiring layer 23.

The first wiring segments 211, the second wiring segments 221, the inner through-wiring segments 271, and the outer through-wiring segment 272 together constitute the winding segment 20. The winding segment 20 functions an electrical inductor. A portion of the magnetic layer 1 constitutes the magnetic core of the winding segment 20.

With reference to FIGS. 10 to 25, the following describes a method for manufacturing a circuit component A1. Note that these figures are oriented to show the top and bottom in the z direction inverted from those shown in FIGS. 5 and 6.

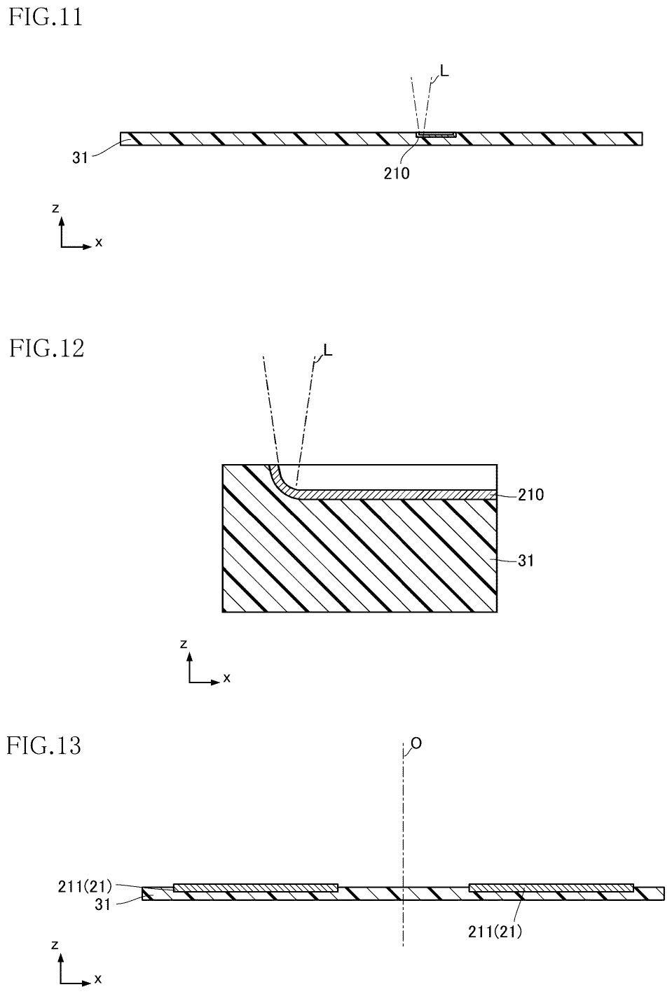

FIGS. 10 and 11 are sectional views taken along the same line as the views shown in FIGS. 5 and 6. First, as shown in the figures, a first insulating layer 31 is prepared. The first insulating layer 31 is made of a resin material containing a metal catalyst, for example. Next, laser light L is applied to the first insulating layer 31. The laser light L is applied to the regions where a first wiring layer 21 (a plurality of first wiring segments 211 and a connecting wiring segment 212) is to be formed. As a result, the resin material forming the first insulating layer 31 is partly removed, creating recesses that are recessed in the Z direction as shown in FIG. 12. In addition, the metal catalyst contained in the first insulating layer 31 precipitates to form a first underlying layer 210. The first underlying layer 210 is thus formed in a shape corresponding to the shape of the first wiring layer 21 (the first wiring segments 211 and the connecting wiring segment 212) to be formed as viewed in the z direction. The first underlying layer 210 is thinner than the depth of the recesses formed by the laser light L.

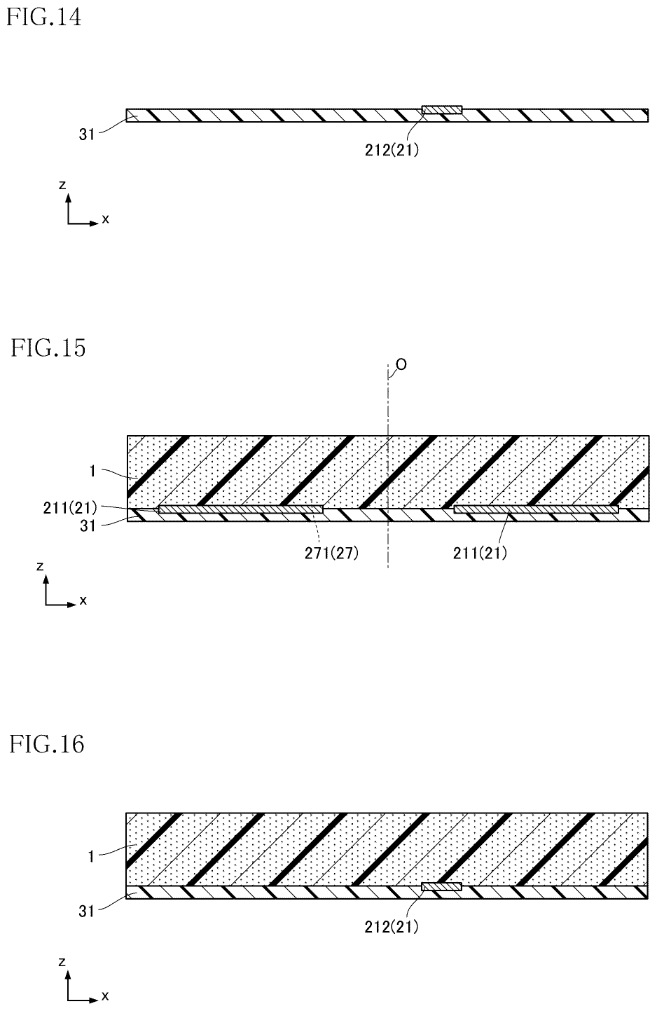

FIGS. 13 and 14 are sectional views taken along the same line as the views shown in FIGS. 5 and 6. As shown in the figures, a first wiring layer 21 is formed. In one example, the first wiring layer 21 is formed by growing a plating layer of copper (Cu) or a copper (Cu) alloy on the first underlying layer 210. As a result, the first wiring layer 21 that includes a plurality of first wiring segments 211 and a connecting wiring segment 212 is obtained. In the illustrated example, the first wiring layer 21 is thicker than the depth of the recesses in the first insulating layer 31. In an alternative manufacturing method, a wiring board formed with a first insulating layer 31 and a first wiring layer 21 may be prepared in advance and used for manufacturing the circuit component A1.

FIGS. 15 and 16 are sectional views taken along the same line as the views shown in FIGS. 5 and 6. As shown in the figures, a magnetic layer 1 is formed. In one example, the magnetic layer 1 is formed by bonding a ferrite substrate or the like prepared in advance to the first insulating layer 31 and the first wiring layer 21. In another example, the magnetic layer 1 is formed by applying a resin paste containing magnetic bodies to the first insulating layer 31 and the first wiring layer 21 and then causing the paste to harden.

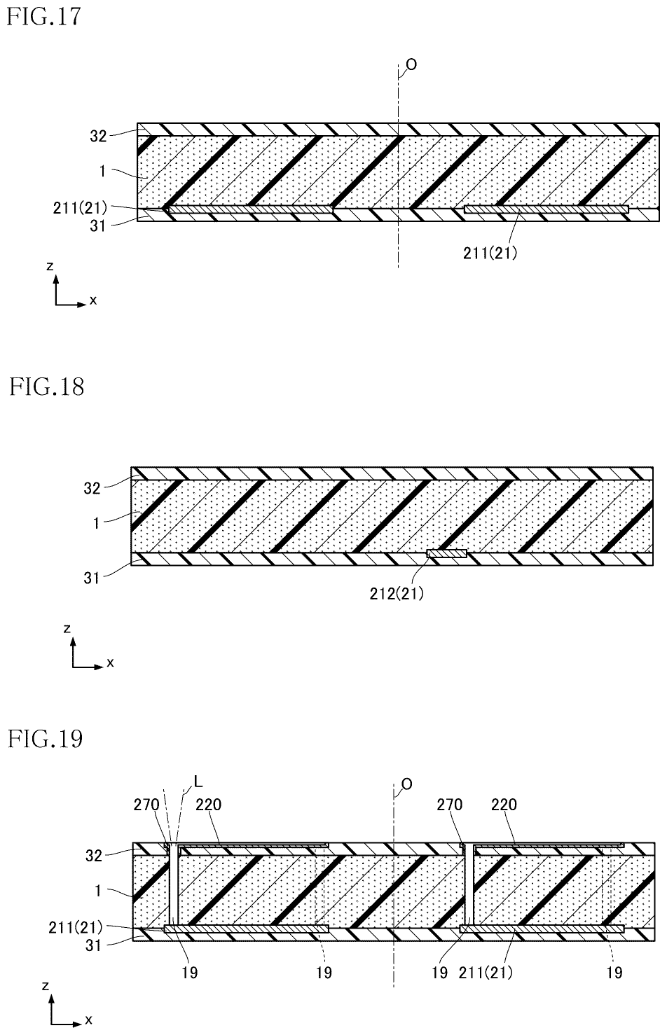

FIGS. 17 and 18 are sectional views taken along the same line as the views shown in FIGS. 5 and 6. As shown in the figures, a second insulating layer 32 is formed. The second insulating layer 32 is made of a resin material containing a metal catalyst, for example. The second insulating layer 32 may be formed in advance and then bonded to the magnetic layer 1, or the second insulating layer 32 may be formed by applying and hardening a material paste.

FIGS. 19 and 20 are sectional views taken along the same line as the views shown in FIGS. 5 and 6. As shown in the figures, laser light L is applied to the second insulating layer 32. The laser light L is applied to the regions where a second wiring layer 22 (a plurality of second wiring a connecting wiring segment 222, segments 221, and a connecting wiring segment 223) is to be formed. As a result, the resin material forming the second insulating layer 32 is partly removed, creating recesses that are recessed in the z direction. In addition, the metal catalyst contained in the second insulating layer 32 precipitates to form a second underlying layer 220. The second underlying layer 220 is thus formed in a shape corresponding to the shape of the second wiring layer 22 (the second wiring segments 221, the connecting wiring segment 222, and the connecting wiring segment 223) to be formed as viewed in the z direction. The second underlying layer 220 is thinner than the depth of the recesses formed by the laser light L.

The laser light L is also applied to irradiate specific regions for specific durations to form a plurality of through-holes 19 penetrating the second insulating layer 32 and the magnetic layer 1. The through-holes 19 are formed at locations where a first through-wiring segment 27 is to be formed. The through-holes 19 extend through the magnetic layer 1 to reach the first wiring layer 21. The process of forming the through-holes 19 forms first-through-wiring underlying layer 270 connected to the second underlying layer 220.

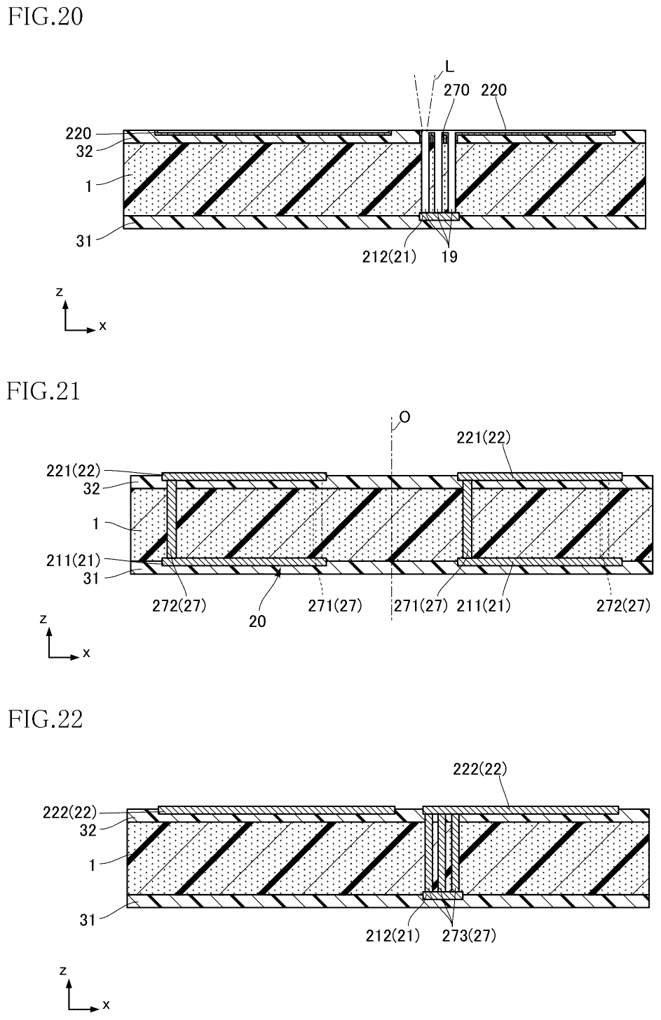

FIGS. 21 and 22 are sectional views taken along the same line as the views shown in FIGS. 5 and 6. As shown in the figures, a second wiring layer 22 is formed. In one example, the second wiring layer 22 is formed by growing a plating layer of copper (Cu) or a copper (Cu) alloy on the second underlying layer 220 and the first-through-wiring underlying layer 270. As a result, the second wiring layer 22 that includes a plurality of second wiring segments 221, a connecting wiring segment 222, and a connecting wiring segment 223 is obtained. In the illustrated example, the second wiring layer 22 is thicker than the depth of the recess in the second insulating layer 32.

The plating process for forming the second wiring layer 22 forms a metal conductor in each through-hole 19. As a result, the first through-wiring segment 27 that includes a plurality of inner through-wiring segments 271, a plurality of outer through-wiring segments 272, and a plurality of connecting through-wiring segments 273 is obtained.

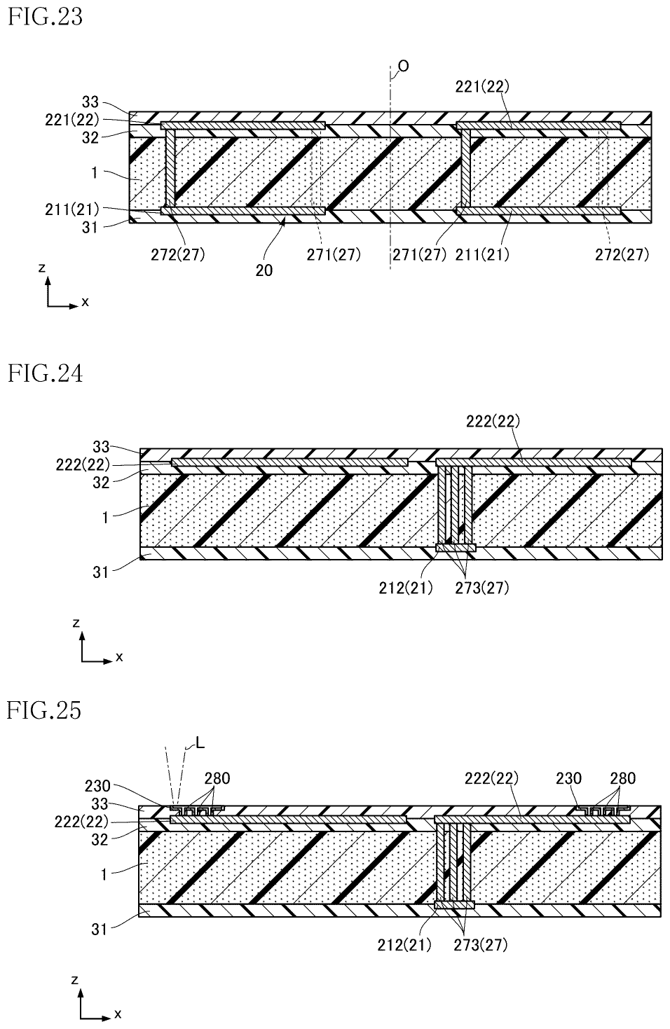

FIGS. 23 and 24 are sectional views taken along the same line as the views shown in FIGS. 5 and 6. As shown in the figures, a third insulating layer 33 is formed. The third insulating layer 33 is made of a resin material containing a metal catalyst, for example. The third insulating layer 33 may be formed in advance and then bonded to the second insulating layer 32 and the second wiring layer 22, or the third insulating layer 33 may be formed by applying and hardening a material paste.

FIG. 25 is a sectional view taken along the same line as the views shown in FIGS. 5 and 6. As shown in the figure, laser light L is applied to the third insulating layer 33. The laser light L is applied to the regions where a third wiring layer 23 (terminal segments 231 and 232) is to be formed. As a result, the resin material forming the third insulating layer 33 is partly removed, creating recesses that are recessed in the z direction. In addition, the metal catalyst contained in the third insulating layer 33 precipitates to form a third underlying layer 230. The third underlying layer 230 is thus formed in a shape corresponding to the shape of the third wiring layer 23 (the terminal segments 231 and 232) as viewed in the z direction. The third underlying layer 230 is thinner than the depth of the recesses formed by applying laser light L.

The laser light L is also applied to specific regions for specific durations to form a plurality of through-holes penetrating the third insulating layer 33 and also to form a second-through-wiring underlying layer 280. The second-through-wiring underlying layer 280 extends to reach the second wiring layer 22.

Subsequently, the third wiring layer 23 is formed. In one example, the third wiring layer 23 is formed by growing a plating layer of copper (Cu) or a copper (Cu) alloy on the third underlying layer 230 and the second-through-wiring underlying layer 280. As a result, the third wiring layer 23 that includes the terminal segments 231 and 232 is obtained. In the illustrated example, the third wiring layer 23 is thicker than the depth of the recess in the third insulating layer 33. Then, additional processes, such as forming a plating layer (not shown) on the terminal segments 231 and 232, may be performed as necessary to obtain the circuit component A1.

### First Embodiment, Electronic Device B1

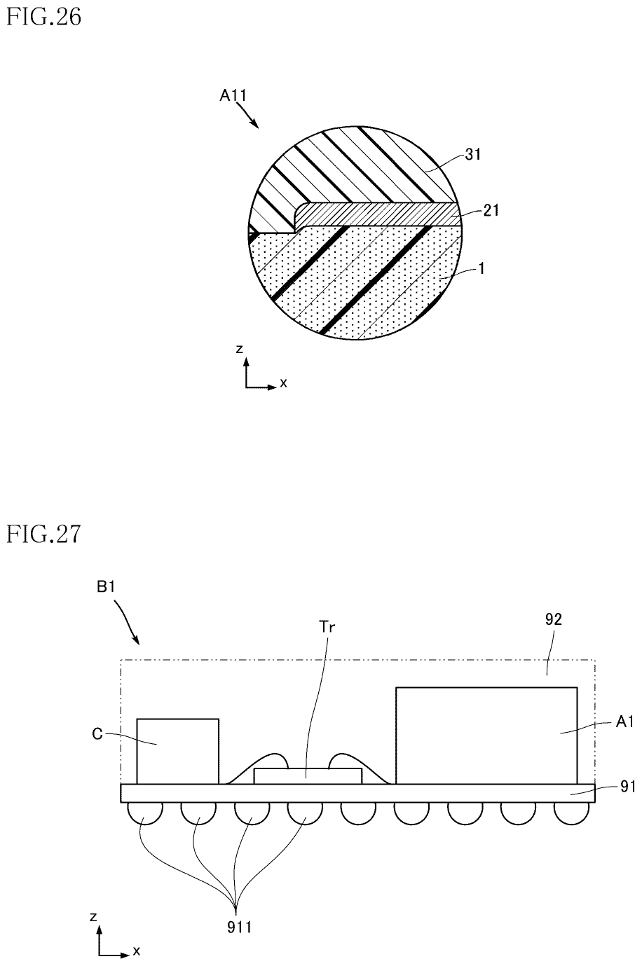

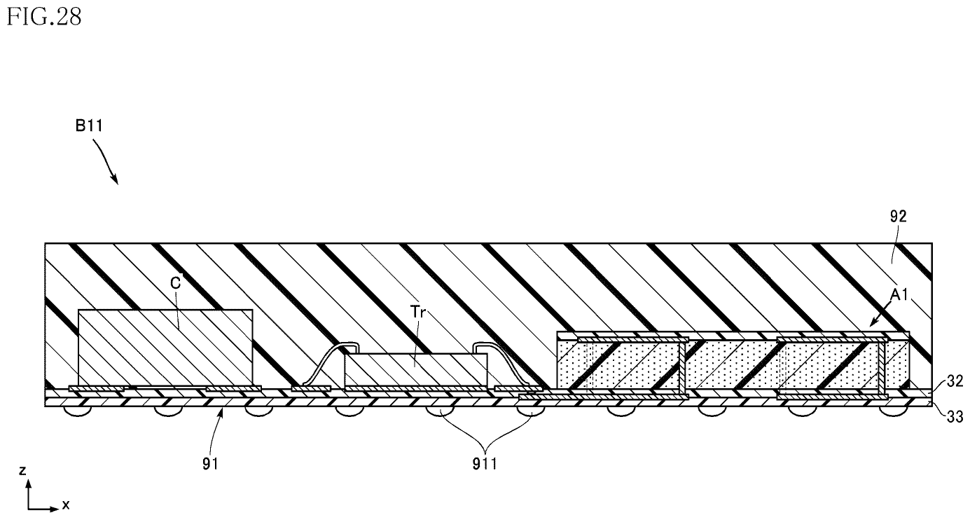

FIG. 27 is a view of an electronic device B1 that includes a circuit component A1. The electronic device B1 includes the circuit component A1, a transistor Tr, a capacitor C, a circuit board 91, and a sealing member 92. FIG. 27 is a front view of the electronic device B1. In FIG. 27, the sealing member 92 is shown in phantom (two-dot-dash line).

The electronic device B1 is provided in a ball grid array (BGA) package, for example. In another example, the electronic device B1 may be provided in a package other than BGA. For instance, the electronic device B1 is a power supply module including the transistor Tr inside.

In one example, the circuit board 91 is a printed board. The circuit board 91 supports the circuit component A1, the transistor Tr, the capacitor C, and the sealing member 92. The circuit board 91 includes a wiring pattern (not shown in the figure) that electrically connects the circuit component A1, the transistor Tr, the capacitor C, and other components. When the circuit component A1 is mounted on the circuit board 91, the surface on which the terminal segments are formed face the circuit board 91, and the terminal segments 231 and 232 are bonded to the circuit pattern. When the electronic device B1 is in a BGA package, the circuit board 91 is formed with a plurality of tiny ball-like electrodes 911 on the surface (lower surface) opposite in the z direction to the surface (upper surface) having the circuit component A1, the transistor Tr, the capacitor C, and the sealing member 92.

The sealing member 92 is formed on the circuit board 91 to cover the circuit component A1, the transistor Tr, the capacitor C, and other components. The sealing member 92 is made of an insulating resin, such as an epoxy resin.

The transistor Tr may be a metal-oxide-semiconductor field-effect transistor (MOSFET), an insulated gate bipolar transistor (IGBT), or a high electron mobility transistor (HEMT), for example. The transistor Tr is made of a semiconductor material, such as Si, SiC, or GaN.

FIGS. 28 to 30 show variations of the electronic device B1. FIG. 28 shows a first variation of the electronic device B1. In an electronic device B11 according to this variation, the circuit board 91 is composed of segments of the second insulating layer 32 and segments of the third insulating layer 33.

In this variation, the second insulating layer 32 and the third insulating layer 33 are larger than the circuit component A1. The transistor Tr and the capacitor C are mounted on the second insulating layer 32. In one example, the wiring pattern of the circuit board 91 may be formed with the second wiring layer 22. In another example, the wiring pattern may be formed with an additional wiring layer formed by applying laser light L to a surface of the second insulating layer 32 opposite to the surface on which the second wiring layer 22 is formed.

In the electronic device B11, the circuit component A1, the transistor Tr, the capacitor C, and other components are not necessarily aligned in the x or y direction. For example, the circuit component A1, the transistor Tr, the capacitor C, and other components may be aligned in the z direction.

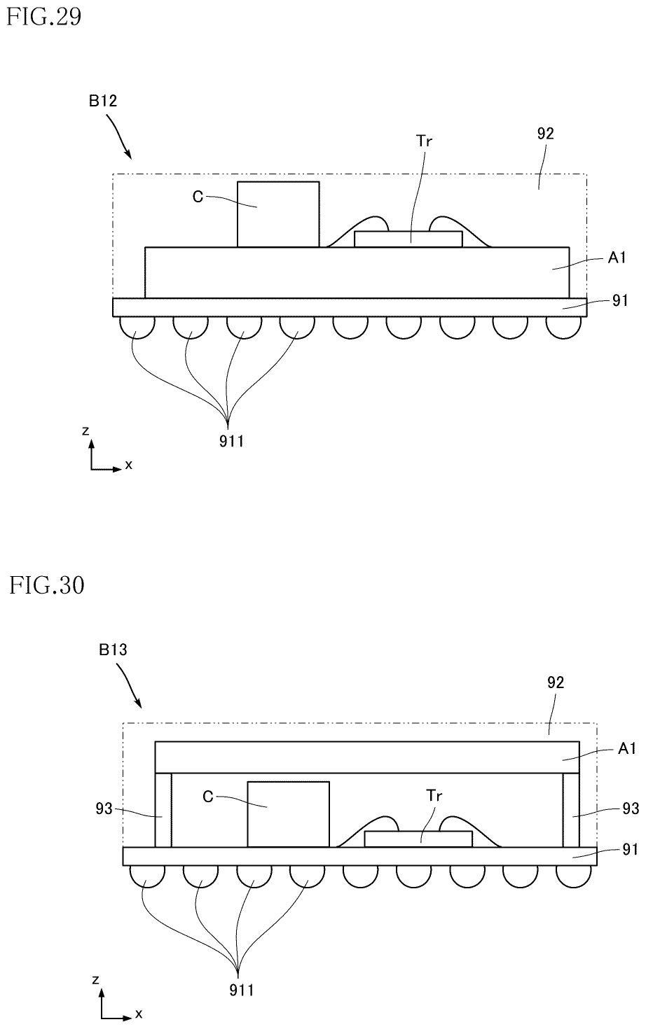

FIG. 29 shows a second variation of the electronic device B1. In an electronic device B12 of this variation, the circuit component A1 is mounted on the circuit board 91, and the transistor Tr and the capacitor C are mounted on the circuit component A1. In other words, the circuit component A1 is directly supported on the circuit board 91, whereas the transistor Tr and the capacitor C are supported indirectly on the circuit board 91 via the circuit component A1.

FIG. 30 shows a third variation of the electronic device B1. In an electronic device B13 of this variation, the transistor Tr and the capacitor C are mounted on the circuit board 91. The circuit component A1 is disposed on the side opposite to the circuit board 91 relative to the transistor Tr and the capacitor C. The circuit component A1 and the circuit board 91 are electrically connected to each other via, for example, a conductive member 93. For example, the conductive member 93 is made of copper (Cu) or the like and penetrates a portion of the sealing member 92 in the z direction.

The following describes effects of the circuit component A1 and the electronic device B1.

According to the present embodiment, the magnetic core of the winding segment 20 is formed by a portion of the magnetic layer 1 as shown in FIG. 5. This eliminates the need for certain processes, such as placing an annular magnetic core within an insulating layer. In addition, the winding segment 20 is provided with the inner through-wiring segments 271 and the outer through-wiring segments 272, each of which penetrates the magnetic layer 1. Therefore, the manufacture of the circuit component A1 can be simplified, and the size of the circuit component A1 can be reduced.

The second insulating layer 32 is made of a material that enables laser direct structuring (LDS), which is used in the production of molded interconnect devices (MIDs), such as a resin material containing a metal catalyst. Thus, as shown in FIG. 19, the stack of the magnetic layer 1 and the second insulating layer 32 can be processed by applying laser light L to collectively form the second underlying layer 220, the first-through-wiring underlying layer 270, and the through-holes 19. This facilitates the manufacture of the circuit component A1. This also ensures that an electrical connection is reliably formed between the second wiring layer 22 and the first through-wiring segment 27. This also helps to ensure that an electrical connection is reliably formed between the first wiring layer 21 and the first through-wiring segment 27.

The circuit component A1 provided with the third insulating layer 33 and the third wiring layer 23 can be readily configured as a surface mountable device. The third insulating layer 33 is made of a material that enables laser direct structuring (LDS), which is used in the production of molded interconnect devices (MIDs), such as a resin material containing a metal catalyst. This allows the third wiring layer 23 and the second through-wiring segments 28 to be formed easily and accurately.

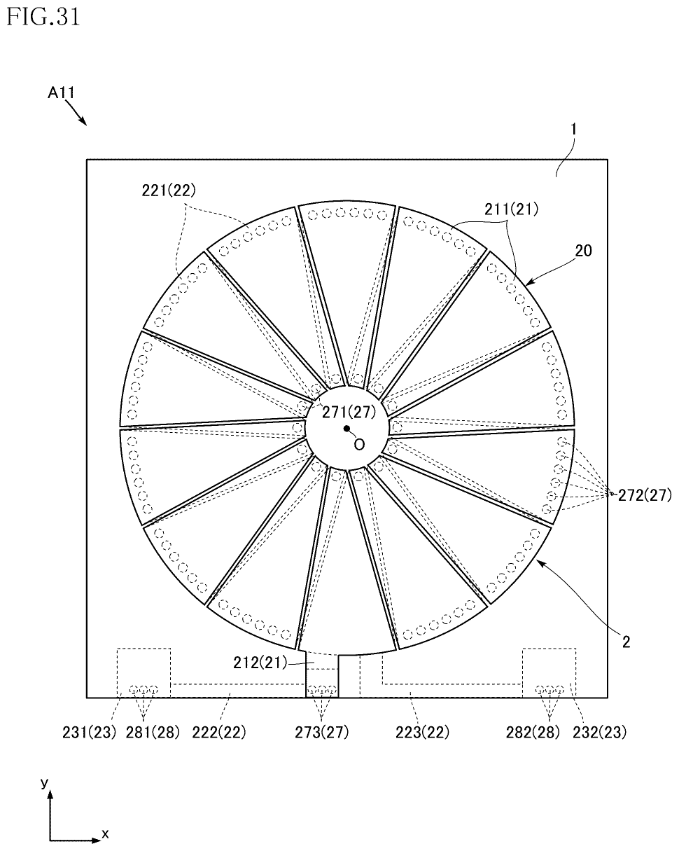

FIGS. 31 to 36 show variations and other embodiments of the present disclosure. In these figures, elements that are identical or similar to those described in the embodiment above are indicated by the same reference numerals.

### First Variation of First Embodiment, Circuit Component A11

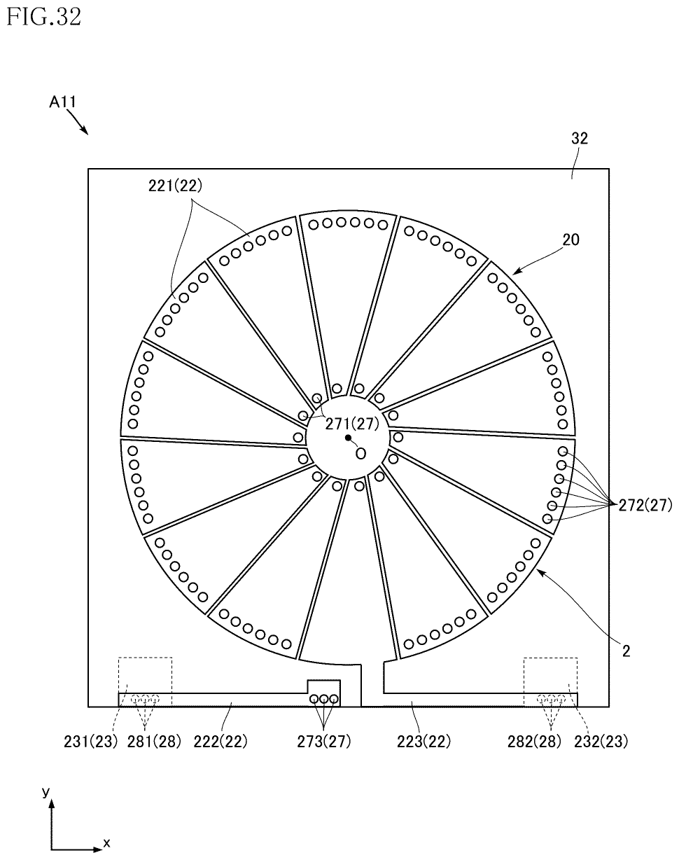

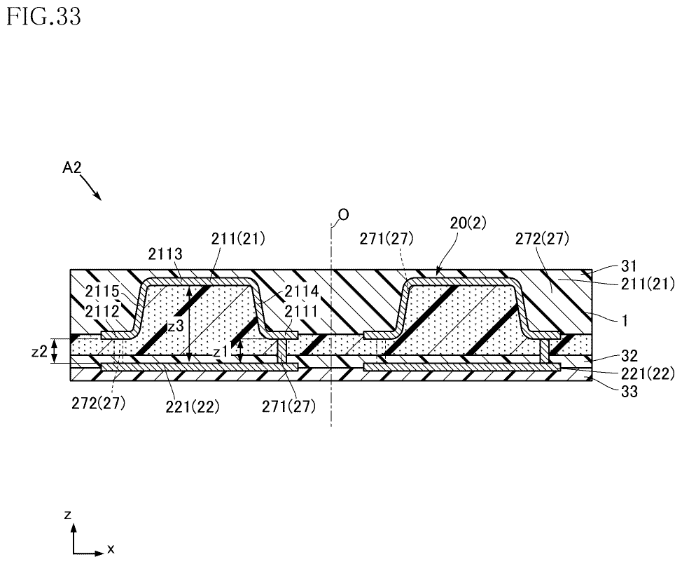

FIGS. 31 and 32 show a circuit component A11 according to a first variation of the circuit component A1. The circuit component A11 differs from the circuit component A1 mainly in the shapes and arrangements of the first wiring segments 211 and the second wiring segments 221.

As viewed in the z direction, each first wiring segment 211 overlaps with two second wiring segments 221 that are next to each other in the circumferential direction. Specifically, one of the two second wiring segments 221 which is located behind clockwise in the circumferential direction and the first wiring segment 211 have respective outer edges located outside in one of the radial directions extending radially from the center O, and these two outer edges corresponds in position in the circumferential direction so that they coincide with each other as viewed in the z direction. Similarly, the other one of the two second wiring segments 221 which is located ahead clockwise in the circumferential direction and the first wiring segment 211 have respective inner edges located inside in the radial direction, and these two inner edges correspond in position in the circumferential direction so that they coincide with each other as viewed in the z direction.

In this variation, one inner through-wiring segment 271 is located in a region where one first wiring segment 211 and one second wiring segment 221 overlap. In addition, six outer through-wiring segments 272 are located in a region where one first wiring segment 211 and one second wiring segment 221 overlap. The numbers of inner through-wiring segments 271 and the outer through-wiring segments 272 are not limited.

This variation simplifies the manufacture of the circuit component A11 and reduces the size of the circuit component A11. The circuit component A11 can be configured to have a greater area of overlap in the z direction between the first wiring segments 211 and the second wiring segments 221 than that in the circuit component A1. As a result, the inductance of the circuit component A11 is increased.

### Second Embodiment, Circuit Component A2

FIG. 33 shows a circuit component according to a second embodiment of the present disclosure. The circuit component A2 of this present embodiment differs from the embodiment described above mainly in the configurations of the magnetic layer 1, the wiring 2, and the first insulating layer 31.

In the present embodiment, each first wiring segment 211 of the first wiring layer 21 includes a first portion 2111, a second portion 2112, a third portion 2113, a fourth portion 2114, and a fifth portion 2115.

The first portion 2111 is the nearest to the center O. The second portion 2112 is spaced apart from the center O. The third portion 2113 is located between the first portion 2111 and the second portion 2112 as viewed in the z direction. The first portion 2111 is at a distance z1 from the second wiring layer 22 (a second wiring segment 221) in the z direction, the second portion 2112 is at a distance z2 from the second wiring layer 22 (a second wiring segment 221), and the third portion 2113 is at a distance z3 from the second wiring layer 22 (a second wiring segment 221), where the distance z3 is greater than the distance z1 or Z2. Preferably, the distance z3 is at least twice as large as either the distance z1 or z2. In the illustrated example, the distance z1 and the distance z2 are equal.

The fourth portion 2114 connects the first portion 2111 and the third portion 2113. The fourth portion 2114 is inclined relative to the z direction. The fifth portion 2115 connects the second portion 2112 and the third portion 2113. The fifth portion 2115 is inclined relative to the z direction.

The first insulating layer 31 and the magnetic layer 1 each have a varying thickness to conform to the shape of the first wiring segments 211. In other words, the first insulating layer 31 is formed with a recess having a bottom along which the third portion 2113 is received. The magnetic layer 1 includes a portion filling the recess in the first insulating layer 31.

This embodiment simplifies the manufacture of the circuit component A2 and reduces the size of the circuit component A2. This embodiment enables reducing the z-direction dimension of the through-holes 19 to be formed in the magnetic layer 1 for forming the inner through-wiring segments 271 and the outer through-wiring segments 272. This results in a reduction in the processing time for forming the through-holes 19 and for plating the inner through-wiring segments 271 and the outer through-wiring segment 272. This embodiment is expected to ensure that the through-holes 19 are plated more reliably.

The portion of the magnetic layer 1 that forms the magnetic core of the winding segment 20 is mostly located between the third portion 2113 and the second wiring segment 221. This helps to prevent the volume of the magnetic core from being reduced. In addition, the first insulating layer 31 is made of a material that enables laser direct structuring (LDS), which is used in the production of molded interconnect devices (MIDs), such as a resin material containing a metal catalyst. This allows the first insulating layer 31 and the first wiring layer 21 having the above-described shape to be formed easily and accurately.

### First Variation of Second Embodiment, Circuit Component A21

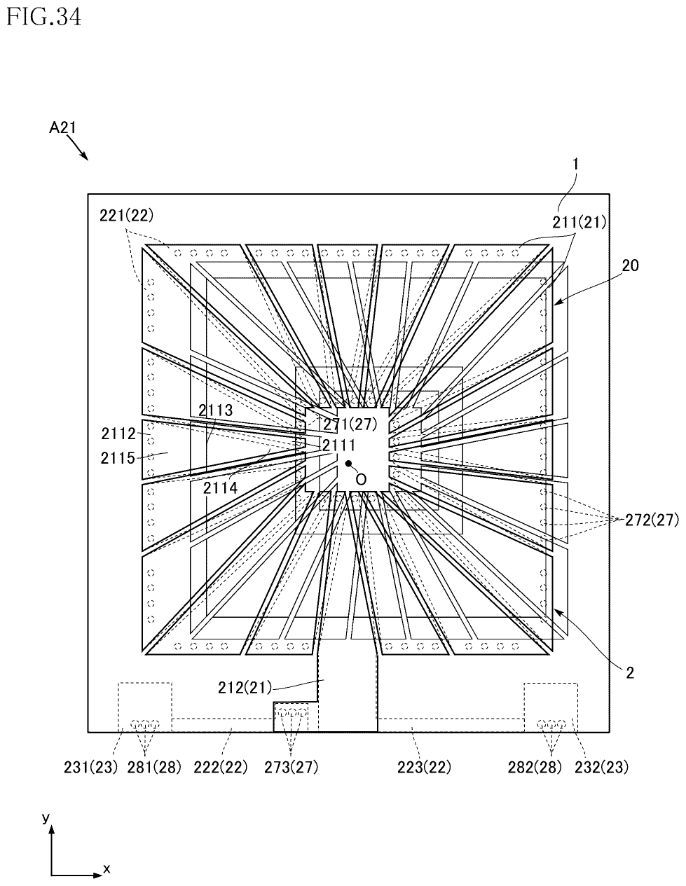

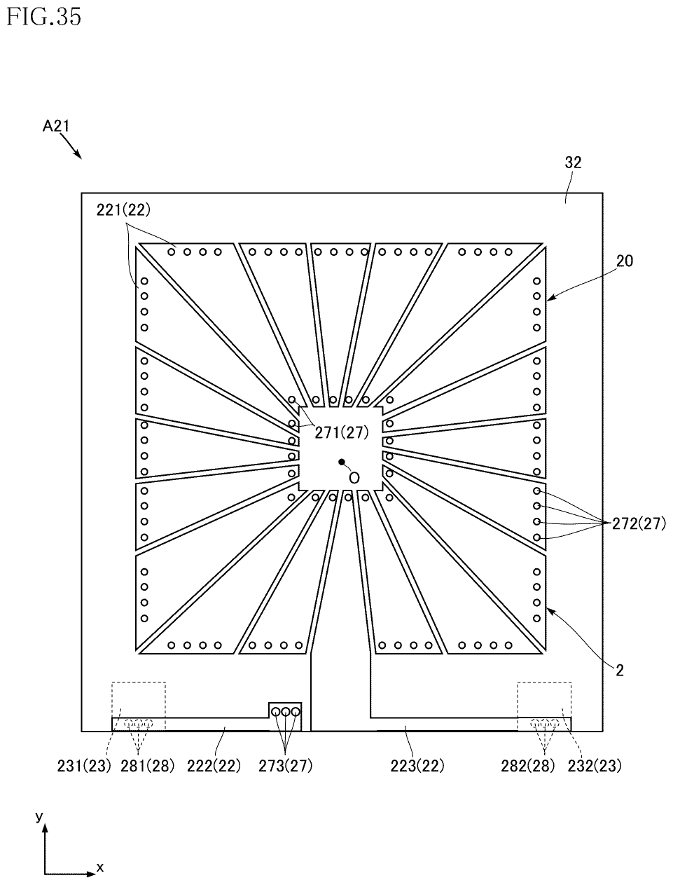

FIGS. 34 and 35 show a circuit component A21 according to a first variation of the circuit component A2. The circuit component A21 differs from the circuit component A1 mainly in the shapes and arrangements of the first wiring segments 211 and the second wiring segments 221.

In this variation, the first wiring segments 211 are arranged in the shape of a rectangular ring surrounding the center O. Similarly, the second wiring segments 221 are arranged in the shape of a rectangular ring surrounding the center O. Each of the first wiring segments 211 and the second wiring segments 221 has a tapered shape.

Similarly to the circuit component A11 and as viewed in the z direction, each first wiring segment 211 overlaps with two second wiring segments 221 that are next to each other in the circumferential direction. Specifically, one of the two second wiring segments 221 which is located behind clockwise in the circumferential direction and the first wiring segment 211 have respective outer edges located outside in one of the radial directions extending radially from the center O, and these two outer edges corresponds in position in the circumferential direction so that they coincide with each other as viewed in the z direction. Similarly, the other one of the two second wiring segments 221 which is located ahead clockwise in the circumferential direction and the first wiring segment 211 have respective inner edges located inside in the radial direction, and these two inner edges correspond in position in the circumferential direction so that they coincide with each other as viewed in the z direction.

In this variation, each first wiring segment 211 includes a first portion 2111, a second portion 2112, a third portion 2113, a fourth portion 2114, and a fifth portion 2115 as described above. One inner through-wiring segment 271 is located in a region where the first portion 2111 of one first wiring segment 211 and one second wiring segment 221 overlap. In addition, four outer through-wiring segments 272 are located in a region where the second portion 2112 of one first wiring segment 211 and one second wiring segment 221 overlap. The numbers of the inner through-wiring segments 271 and the outer through-wiring segments 272 are not limited.

This variation simplifies the manufacture of the circuit component A21 and reduces the size of the circuit component A21. As can be understood from this variation, as long as the first wiring segments 211 and the second wiring segments 221 are arranged to surround the center O, the overall shape is not limited to an annular ring, and various other shapes, including the shape of a rectangular ring, are possible. This arrangement in a rectangular ring or other shapes can also be used for wiring segments that do not include the first portion 2111, the second portion 2112, the third portion 2113, the fourth portion 2114, and the fifth portion 2115, as those of the circuit component A1.

### Variation of Magnetic Layer 1:

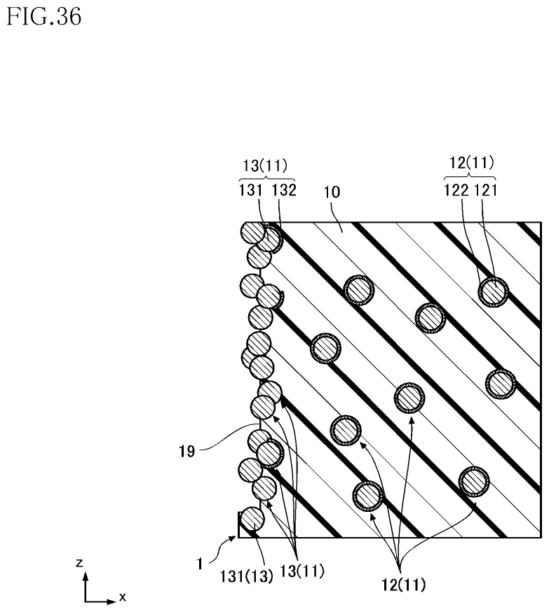

FIG. 36 shows a variation of the magnetic layer 1. The magnetic layer 1 of this variation is made of a resin material 10 containing magnetic particles 11. The magnetic particles 11 occupy at least 60% and at most 90% of the magnetic layer 1 in volume. The relative permeability of the magnetic layer 1, which is the permeability of a compound of the resin material 10 and the magnetic particles 11, is 10 or higher, for example. While the relative permeability of the magnetic layer 1 is not limited to 10, a relative permeability of 10 or higher is preferable for the circuit components A1 and A2 to achieve practical inductance values. The resin material 10 may be a thermosetting resin, examples of which include an epoxy resin and a phenolic resin. The magnetic particles 11 include first particles 12 and second particles 13.

The first particles 12 are dispersed in the resin material 10. Each first particle 12 includes a first core 121 and an insulating coating film 122.

The first core 121 is made of a magnetic metal powder. As the magnetic metal powder, a material containing a metallic element that exhibits ferromagnetism alone is preferable. Examples of such materials include those containing one or more of Fe, Co, and Ni (such as Fe, Co, Ni, or an alloy or compound of Fe, Co, and/or Ni). The insulating coating film 122 covers the entire surface of the first core 121. In one example, the insulating coating film 122 is made of an oxide of the material forming the first core 121. In another example, the insulating coating film 122 is made of silicon oxide, silicon nitride, or an insulating resin, instead of the oxide of a material forming the first core 121. Since the insulating coating film 122 covers the entire surface of the first core 121, each first particle 12 is insulating. The first cores 121 have a diameter ranging, for example, from several hundred nanometers to several tens of micrometers. The insulating coating films 122 have a thickness ranging, for example, from several nanometers to several tens of nanometers. Instead of having the insulating coating film 122 covering the entire surface of the first core 121, each first particle 12 may achieve insulation by being composed entirely of an oxide-based magnetic material, such as ferrite.

When the through-holes are formed as described above, the second particles 13 form an underlying metal layer that coats the inner surface of each through-hole 19. Each second particle 13 includes a second core 131.

The second cores 131 are made of a magnetic metal powder. The magnetic metal powder is the same as the magnetic metal powder that forms the first cores 121. That is, as the magnetic metal powder of the second cores 131, a material containing a metallic element that exhibits ferromagnetism alone is preferable, and examples of such materials include those containing one or more of Fe, Co, and Ni. The diameter of the second cores 131 is the same as the diameter of the first cores 121.

Each second particle 13 may have an insulating coating film 132 covering the surface of the second core 131 such that at least a portion of the surface is exposed. In one example, the insulating coating film 132 is made of an oxide of the material forming the second core 131. The insulating coating film 122 is made of the same material as that of the insulating coating film 132. In another example, the insulating coating film 132 is made of silicon oxide, silicon nitride, or an insulating resin, instead of the oxide of a material forming the second core 131. When the second particles 13 have the insulating coating films 132, the surfaces of the second cores 131 exposed from the insulating coating films 132 are in contact with the wiring 2. The thickness of the insulating coating films 132 is the same as the thickness of the insulating coating films 122.

With the magnetic layer 1 according to this variation, an underlying layer that covers the inner surface of each through-hole 19 is obtained. This allows the first through-wiring segment 27 to be formed easily and reliably.

The circuit component, the electronic device, and the method for manufacturing a circuit component are not limited to the embodiments described above. Various design changes can be made to the specific configurations of the circuit component, the electronic device, and the method for manufacturing a circuit component according to the present disclosure.

### Clause 1.

A circuit component comprising:
a magnetic layer;
a first insulating layer stacked on a first side in a thickness direction relative to the magnetic layer;
a second insulating layer stacked on a second side in the thickness direction relative to the magnetic layer; and
a wiring that includes a first wiring layer located between the magnetic layer and the first insulating layer, a second wiring layer located on the second side in the thickness direction relative to the second insulating layer, and a first through-wiring segment penetrating the magnetic layer and the second insulating layer and connected to the first wiring layer and the second wiring layer,
wherein the first wiring layer, the second wiring layer, and the first through-wiring segment constitute a winding segment.

### Clause 2.

The circuit component according to Clause 1, wherein the first wiring layer includes a plurality of first wiring segments, and
the plurality of first wiring segments are arranged to surround a center as viewed in the thickness direction.

### Clause 3.

The circuit component according to Clause 2, wherein the second wiring layer includes a plurality of second wiring segments, and
the plurality of second wiring segments are arranged to surround the center as viewed in the thickness direction.

### Clause 4.

The circuit component according to Clause 3, wherein two first wiring segments next to each other among the plurality of first wiring segments partially overlap with one of the plurality of second wiring segments as viewed in the thickness direction, and
two second wiring segments next to each other among the plurality of second wiring segments partially overlap with one of the plurality of first wiring segments as viewed in the thickness direction.

### Clause 5.

The circuit component according to Clause 3 or 4, wherein the plurality of first wiring segments are flat in shape.

### Clause 6.

The circuit component according to Clause 3 or 4, wherein the plurality of first wiring segments include a first portion, a second portion located farther from the center than the first portion, and a third portion located between the first portion and the second portion as viewed in the thickness direction,
a distance between the third portion and the plurality of second wiring segments in the thickness direction is greater than a distance between the first portion and the plurality of second wiring segments in the thickness direction and a distance between the second portion and the plurality of second wiring segments in the thickness direction, and
the first through-wiring segment includes an inner through-wiring segment connected to the first portion and the plurality of second wiring segments and an outer through-wiring segment connected to the second portion and the plurality of second wiring segments.

### Clause 7.

The circuit component according to any one of Clauses 1 to 6, wherein the first wiring layer is embedded in the first insulating layer in the thickness direction.

### Clause 8.

The circuit component according to Clause 7, wherein the first wiring layer is embedded in the magnetic layer in the thickness direction.

### Clause 9.

The circuit component according to any one of Clauses 1 to 6, comprising a third insulating layer stacked on the second side in the thickness direction relative to the second insulating layer,
wherein the second wiring layer is located between the second insulating layer and the third insulating layer.

### Clause 10.

The circuit component according to Clause 9, wherein the second wiring layer is embedded in the second insulating layer in the thickness direction.

### Clause 11.

The circuit component according to Clause 10, wherein the second wiring layer is embedded in the third insulating layer in the thickness direction.

### Clause 12.

The circuit component according to any one of Clauses 9 to 11, wherein the wiring further includes a third wiring layer located on the second side in the thickness direction relative to the third insulating layer.

### Clause 13.

The circuit component according to Clause 12, wherein the wiring further includes a second through-wiring segment penetrating the third insulating layer and connected to the second wiring layer and the third wiring layer.

### Clause 14.

An electronic device comprising:
the circuit component according to any one of Clauses 1 to 13; and
an electronic component electrically connected to the circuit component.

### Clause 15.

The electronic device according to Clause 14, wherein the electronic component is a transistor.

### Clause 16.

The electronic device according to Clause 14 or 15, wherein a portion of the second insulating layer is included in a circuit board on which the electronic component is mounted.

### Clause 17.

A method for manufacturing a circuit component, the method comprising:
preparing a first insulating layer and a first wiring layer stacked in a thickness direction;
stacking a magnetic layer on a side of the first wiring layer opposite to the first insulating layer;
stacking a second insulating layer on a side of the magnetic layer opposite to the first insulating layer; and
forming a second wiring layer on a side of the second insulating layer opposite to the magnetic layer, and forming a first through-wiring segment that penetrates the magnetic layer and the second insulating layer and is connected to the first wiring layer and the second wiring layer,
wherein the forming the second wiring layer and the first through-wiring segment includes forming a second underlying layer of a conductor by irradiating the second insulating layer with laser light.

### Clause 18.

The method according to Clause 17, wherein the preparing the first insulating layer and the first wiring layer includes forming a first underlying layer of a conductor by irradiating the first insulating layer with laser light.

### REFERENCE NUMERALS

A1, A2: circuit component
B1, B11: electronic device
1: magnetic layer
2: wiring
10: resin material
11: magnetic particle
12: first particle
13: second particle
19: through-hole
20: winding segment
21: first wiring layer
22: second wiring layer
23: third wiring layer
27: first through-wiring segment
28: second through-wiring segment
31: first insulating layer
32: second insulating layer
33: third insulating layer
35: terminal segment
91: circuit board
93: conductive member
92: sealing member
121: first core
122: insulating coating film
131: second core
132: insulating coating film
210: first underlying layer
211: first wiring segment
212: connecting wiring segment
220: second underlying layer
221: second wiring segment
222: connecting wiring segment
223: connecting wiring segment
230: third underlying layer
231: terminal segment
232: terminal segment
270: first-through-wiring underlying layer
271: inner through-wiring segment
272: outer through-wiring segment
273: connecting through-wiring segment
280: second-through-wiring underlying layer
911: electrode
2111: first portion
2112: second portion
2113: third portion
2114: fourth portion
2115: fifth portion
C: capacitor
L: laser light
O: center
Tr: transistor
z1, z2, z3: distance

1. A circuit component comprising:
a magnetic layer;
a first insulating layer stacked on a first side in a thickness direction relative to the magnetic layer;
a second insulating layer stacked on a second side in the thickness direction relative to the magnetic layer; and
a wiring that includes a first wiring layer located between the magnetic layer and the first insulating layer, a second wiring layer located on the second side in the thickness direction relative to the second insulating layer, and a first through-wiring segment penetrating the magnetic layer and the second insulating layer and connected to the first wiring layer and the second wiring layer,
wherein the first wiring layer, the second wiring layer, and the first through-wiring segment constitute a winding segment.

2. The circuit component according to claim 1, wherein the first wiring layer includes a plurality of first wiring segments, and
the plurality of first wiring segments are arranged to surround a center as viewed in the thickness direction.

3. The circuit component according to claim 2, wherein the second wiring layer includes a plurality of second wiring segments, and
the plurality of second wiring segments are arranged to surround the center as viewed in the thickness direction.

4. The circuit component according to claim 3, wherein two first wiring segments next to each other among the plurality of first wiring segments partially overlap with one of the plurality of second wiring segments as viewed in the thickness direction, and
two second wiring segments next to each other among the plurality of second wiring segments partially overlap with one of the plurality of first wiring segments as viewed in the thickness direction.

5. The circuit component according to claim 3, wherein the plurality of first wiring segments are flat in shape.

6. The circuit component according to claim 3, wherein the plurality of first wiring segments include a first portion, a second portion located farther from the center than the first portion, and a third portion located between the first portion and the second portion as viewed in the thickness direction,
a distance between the third portion and the plurality of second wiring segments in the thickness direction is greater than a distance between the first portion and the plurality of second wiring segments in the thickness direction and a distance between the second portion and the plurality of second wiring segments in the thickness direction, and
the first through-wiring segment includes an inner through-wiring segment connected to the first portion and the plurality of second wiring segments and an outer through-wiring segment connected to the second portion and the plurality of second wiring segments.

7. The circuit component according to claim 1, wherein the first wiring layer is embedded in the first insulating layer in the thickness direction.

8. The circuit component according to claim 7, wherein the first wiring layer is embedded in the magnetic layer in the thickness direction.

9. The circuit component according to claim 1, comprising a third insulating layer stacked on the second side in the thickness direction relative to the second insulating layer,
wherein the second wiring layer is located between the second insulating layer and the third insulating layer.

10. The circuit component according to claim 9, wherein the second wiring layer is embedded in the second insulating layer in the thickness direction.

11. The circuit component according to claim 10, wherein the second wiring layer is embedded in the third insulating layer in the thickness direction.

12. The circuit component according to claim 9, wherein the wiring further includes a third wiring layer located on the second side in the thickness direction relative to the third insulating layer.

13. The circuit component according to claim 12, wherein the wiring further includes a second through-wiring segment penetrating the third insulating layer and connected to the second wiring layer and the third wiring layer.

14. An electronic device comprising:
the circuit component according to claim 1; and
an electronic component electrically connected to the circuit component.

15. The electronic device according to claim 14, wherein the electronic component is a transistor.

16. The electronic device according to claim 14, wherein a portion of the second insulating layer is included in a circuit board on which the electronic component is mounted.

17. A method for manufacturing a circuit component, the method comprising:
preparing a first insulating layer and a first wiring layer stacked in a thickness direction;
stacking a magnetic layer on a side of the first wiring layer opposite to the first insulating layer;
stacking a second insulating layer on a side of the magnetic layer opposite to the first insulating layer; and
forming a second wiring layer on a side of the second insulating layer opposite to the magnetic layer, and forming a first through-wiring segment that penetrates the magnetic layer and the second insulating layer and is connected to the first wiring layer and the second wiring layer,
wherein the forming the second wiring layer and the first through-wiring segment includes forming a second underlying layer of a conductor by irradiating the second insulating layer with laser light.

18. The method according to claim 17, wherein the preparing the first insulating layer and the first wiring layer includes forming a first underlying layer of a conductor by irradiating the first insulating layer with laser light.
